(19) United States
(12) Patent Application Publication
(10) Pub. No.: US 2007/0155981 A1
(43) Pub. Date: Jul. 5, 2007

(54) Arylene derivative and organic light emitting device manufactured using the same

(76) Inventors: Dong-Woo Shin, Seoul (KR); Woon-Jung Paek, Yongin-si (KR); Tae-Yong Noh, Gunpo-si (KR); O-Hyun Kwon, Seoul (KR); Jong- Jin Park, Yongin-si (KR); Myeong-Suk Kim, Suwon-si (KR); Byoung-Ki Choi, Hwaseong-si (KR)

Correspondence Address: Robert E. Bushnell, 1522 K Street, N.W., Suite 300, Washington, DC, 20005, US

(21) Appl. No.: 11/633,004

(22) Filed: Dec. 4, 2006

(30) Foreign Application Priority Data
Dec. 31, 2005 (KR) 10-2005-0136270

(51) Int. Cl. H01L 51/54; C09K 11/06

(52) U.S. Cl. 560/8; 560/19; 548/440; 428/690; 428/917; 313/504; 313/506; 257/E51.049; 257/E51.051

(57) ABSTRACT

Provided is an arylene derivative including a polar functional group represented by Formula 1:

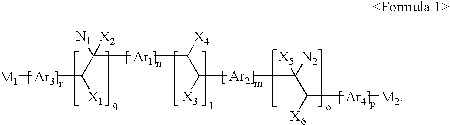

An arylene derivative including a polar functional group has excellent solubility in an organic solvent. A soluble compound of the arylene derivative can be used to form a thermally stable organic layer which can be used to form an organic light emitting device having low operating voltage, high efficiency, and excellent brightness.

### CROSS-REFERENCE TO RELATED PATENT APPLICATION AND CLAIM OF PRIORITY

This application claims the benefit of Korean Patent Application No. 10-2005-0136270, filed on Dec. 31, 2005, in the Korean Intellectual Property Office, the disclosure of which is incorporated herein in its entirety by reference.

### BACKGROUND OF THE INVENTION

1. Field of the Invention

The present invention relates to an arylene derivative and an organic light emitting device, and more particularly, to an arylene derivative including a functional group enabling the arylene derivative to dissolve in an organic solvent and having improved solubility in an organic solvent, and to an organic light emitting device having a layer in which the arylene derivative is included.

2. Description of the Related Art

Light-emitting devices are devices that generate and emit light and have wide angles of light emission, excellent contrast, and short response times. Light emitting devices can be categorized into inorganic light emitting devices having light emitting layers formed of inorganic compounds and organic light emitting devices (OLEDs) having light emitting layers formed of organic compounds. OLEDs have high brightness, low operating voltages, and short response times, and can realize emission of a wide range of colors, when compared to inorganic light emitting devices. As a result, a lot of research into OLEDs has been conducted.

In general, an OLED has a layered structure of anode/organic light emitting layer/cathode. In addition, an OLED can have various layered structures such as a structure of anode/hole injection layer/hole transport layer/light emitting layer/electron transport layer/electron injection layer/cathode or a structure of anode/hole injection layer/hole transport layer/light emitting layer/hole blocking layer/electron transport layer/electron injection layer/cathode.

Materials used to manufacture OLEDs can be categorized into vacuum deposition materials and solution coating materials according to a method of preparing a corresponding organic layer. A vacuum deposition material should be formed using a vapor pressure of 10⁻⁶ torr or higher at 500° C. or less and may be a material having a molecular weight of 1200 or less. A solution coating material should have high solubility in a solvent such that it can be prepared in a liquid state and includes aromatic compounds or heterocyclic compounds.

When an organic light emitting device is manufactured using a vacuum deposition method, a vacuum system is required and thus manufacturing costs increase, and when a shadow mask is used to define a pixel used for displaying natural color, it is difficult to obtain a pixel having high resolution. On the other hand, a solution coating method (also called as a wet method), such as an inkjet printing method, a screen printing method, or a spin coating method, can be easily used, is inexpensive, and can be used to obtain a relatively higher pixel resolution than when a shadow mask is used.

Even when the performance is excellent, an organic layer formed using above methods is gradually crystallized such that the size of the formed crystals corresponds to a wavelength of visible light. As a result, visible rays are scattered, a whitening effect may take place, and pinholes can be formed so that thus a device may easily deteriorate by a thermal-aging.

Therefore, manufacturing materials and organic light emitting devices having improved properties which overcome limitations of the method and materials described above has been developed.

For example, WO03/037836 discloses a light emitting material having improved solubility by introducing a silyl group to a distyrylarylene derivative. J.Am.Chem.Soc. 2004, 126, 1596 discloses a symmetrical α,ω-substituted sexithiophene derivative containing thermally removable branched ester solubilizing groups, and Synthet. Metal. 119 (2001), 311 discloses the use of sulfinyl groups as thermally eliminable groups in precursor routes towards conjugated systems, like OC[1]C[10]-PPV.

However, development of an organic light emitting device including a new arylene derivative which has a low molecular weight and can be manufactured using a solution coating method instead of a vacuum depositing method is required wherein the organic light emitting device has a convenient manufacturing process, relatively high resolution, which the solution coating method usually provides, and excellent thermal stability and brightness.

### SUMMARY OF THE INVENTION

The present invention provides an arylene derivative including a polar functional group.

The present invention also provides an organic light emitting device manufactured using the arylene derivatives.

The present invention also provides a method of manufacturing an organic light emitting device using the arylene derivatives.

According to an aspect of the present invention, there is provided an arylene derivative represented by Formula 1:

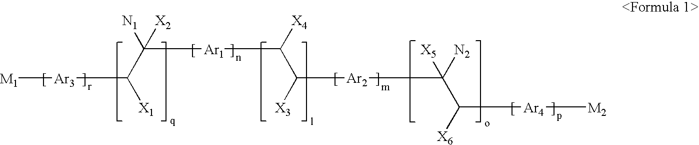

where Ar₁, Ar₂, Ar₃, and Ar₄ are each independently a substituted or unsubstituted C₆-C₃₀ arylene group, or a substituted or unsubstituted C₂-C₃₀ heteroarylene group;

M₁ and M₂ are each independently hydrogen,

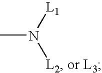

L₁, L₂, and L₃ are each independently a substituted or unsubstituted C₆-C₃₀ aryl group or a substituted or unsubstituted C₂-C₃₀ heteroaryl group; L₁ and L₂ may be connected to form a substituted or unsubstituted ring with the N atom;

N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;

at least one of X₁ and X₂, X₃ and X₄, and X₅ and X₆ are

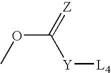

where Y is sulfur, carbon, nitrogen, or oxygen, Z is sulfur or oxygen, L₄ is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, a substituted or unsubstituted C₂-C₃₀ heteroaryl group, an alkoxy group, an alkylamine group, or a thioalkyl group;

l, o and q are each integers of 0 or 1;

1+o+q is an integer of 1 through 3; and

m, n, p and r are each integers of 0 through 3.

According to another aspect of the present invention, there is provided an organic light emitting device including: a first electrode; a second electrode; and an organic layer interposed between the first electrode and the second electrode, the organic layer formed by forming a layer having an arylene derivative represented by Formula 1 and thermolyzing the layer having the arylene derivative.

According to another aspect of the present invention, there is provided an organic light emitting device including: a first electrode; a second electrode; and an organic layer interposed between the first electrode and the second electrode, the organic layer formed by forming a layer comprising the arylene derivative of claim 1 by a wet method or a laser induced thermal imaging method and thermolyzing the layer comprising the arylene derivative.

According to another aspect of the present invention, there is provided a method of manufacturing an organic light emitting device including: forming an organic layer including the arylene derivative and thermolyzing the organic layer.

An arylene derivative including a polar functional group has excellent solubility in an organic solvent. An organic light emitting device manufactured using the arylene derivative can form a thermally stable organic layer and has a lower operating voltage, higher efficiency, and more excellent brightness than a conventional organic light emitting device manufactured using a vapor deposition, resulting in deterioration of the property of the device.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A through 1C are sectional views schematically illustrating structures of organic light emitting devices according to embodiments of the present invention;

FIG. 2 is a graph of the absorption spectra and photoluminescence of a compound 2 according to an embodiment of the present invention;

FIG. 3 is a graph illustrating the experimental result of a thermogravimetric analysis (TGA) for a compound 2 according to an embodiment of the present invention; and

FIG. 4 is a graph illustrating results of an infrared experiment performed on a compound 2 according to an embodiment of the present invention before and after heat treatment.

### DETAILED DESCRIPTION OF THE INVENTION

Hereinafter, the present invention will be described more fully.

An arylene derivative according to an embodiment of the present invention is represented by formula 1:

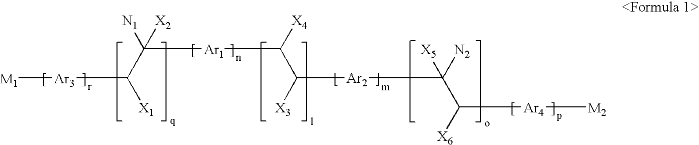

where Ar₁, Ar₂, Ar₃, and Ar₄ are each independently a substituted or unsubstituted C₆-C₃₀ arylene group, or a substituted or unsubstituted C₂-C₃₀ heteroarylene group;

M₁ and M₂ are each independently hydrogen,

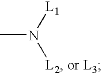

L₁, L₂, and L₃ are each independently a substituted or unsubstituted C₆-C₃₀ aryl group or a substituted or unsubstituted C₂-C₃₀ heteroaryl group; L₁ and L₂ may be connected to form a substituted or unsubstituted ring with the N atom;

N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;

at least one of X₁ and X₂, X₃ and X₄, and X₅ and X₆ are

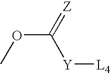

where Y is sulfur, carbon, nitrogen, or oxygen, Z is sulfur or oxygen, and L₄ is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀aryl group, a substituted or unsubstituted C₂-C₃₀ heteroaryl group, an alkoxy group, an alkylamine group, or a thioalkyl group;

l, o and q are each integers of 0 or 1;

1+o+q is an integer of 1 through 3; and

m, n, p and r are each integers of 0 through 3.

The arylene derivatives have excellent solubility in an organic solvent and thus, an organic layer can be manufactured using a wet coating method such as a spin coating method. In addition, the bonded polar functional group is easily decomposed by heat, so when a baking process is performed, a polar functional group is vaporized and removed and a styryl-based compound having a vinyl group remains.

The arylene derivatives may have a solubility of 0.1 to 10% by weight at 20° C. A solvent in which the arylene derivatives are dissolved is not particularly restricted and may be any solvent used commonly in the field.

In the arylene derivatives described above, the compound represented by Formula 1 may be a compound represented by Formula 1a below:

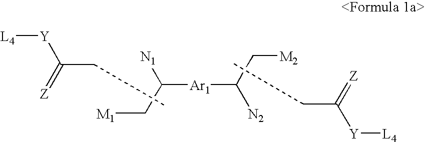

where Ar₁, M₁, M₂, N₁, N₂, L₄, Y, and Z are defined as above.

Also, in the arylene derivatives, the compound represented by Formula 1 may be a compound represented by Formula 1b below:

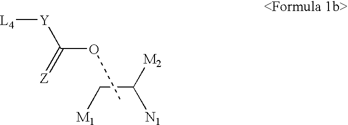

where M₁, M₂, N₁, L₄, Y, and Z are defined as above.

The dotted line of Formulas 1a and 1b can be selectively connected to the carbon located at both ends of the solid line which intersects with the dotted line.

More specifically, in the arylene derivatives represented by Formula 1, Ar₁, Ar₂, Ar₃, and Ar₄ are each independently a substituted or unsubstituted phenylene group, a substituted or unsubstituted naphthalene group, a substituted or unsubstituted anthracene group, a substituted or unsubstituted phenanthrene group, a substituted or unsubstituted fluorene group, a substituted or unsubstituted carbazoyl group, a substituted or unsubstituted thiophene group, or a substituted or unsubstituted thiazole group;

M₁ and M₂ are each independently hydrogen,

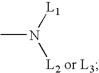

L₁, L₂, and L₃ are each independently, a substituted or unsubstituted phenyl group, a substituted or unsubstituted naphthalene group, a substituted or unsubstituted anthracene group, or a substituted or unsubstituted phenanthrene group; L₁ and L₂ may be connected each other to form a substituted or unsubstituted ring with the N atom but are not limited thereto.

In addition, the arylene derivatives represented by Formula 1, and the substituents of the alkyl group, the aryl group, the heteroaryl group, and the cycloalkyl group may be at least one selected from the group consisting of —F, —Cl, —Br, —CN, —NO₂, —OH, a C₁-C₂₀alkyl group unsubstituted or substituted for —F, —Cl, —Br, —CN, —NO₂, or —OH, a C₁-C₂₀alkoxy group unsubstituted or substituted for —F, —Cl, —Br, —CN, —NO₂, or —OH, a C₆-C₃₀ aryl group unsubstituted or substituted for —F, —Cl, —Br, —CN, —NO₂, or —OH, a C₂-C₃₀ heteroaryl group unsubstituted or substituted for —F, —Cl, —Br, —CN, —NO₂, or —OH, and a C₅-C₂₀ cycloalkyl group unsubstituted or substituted for —F, —Cl, —Br, —CN, —NO₂, or —OH but are not limited thereto.

More specifically, in the arylene derivatives represented by Formula 1, examples of Ar₁, Ar₂, Ar₃, and Ar₄ may be each independently, phenylene group, C₁-C₁₀ dicyanophenylene group, trifluoromethoxyphenylene group, o-, m-, or p-tolylene group, o-, m-, or p-cumenylene group, mesitylene group, phenoxyphenylene group, (α,α-dimethylbenzene)phenylene group, (N,N′-dimethyl)aminophenylene group, (N,N′-diphenyl)aminophenylene group, (C₁-C₁₀alkylcyclohexyl)phenylene group, (anthryl)phenylene group, biphenylene group, C₁-C₁₀ alkylbiphenylene group, C₁-C₁₀ alkoxybiphenylene group, pentalenyl group, indenylene group, naphthylene group, C₁-C₁₀alkylnaphthylene group, C₁-C₁₀ alkoxynaphthylene group, halonaphthylene group, cyanonaphthylene group, biphenylenylene group, C₁-C₁₀ alkyl biphenylenylene group, C₁-C₁₀ alkoxy biphenylenylene group, anthrylene group, biphenylanthrylene group, azulenylene group, heptalenylene group, acenaphthylenylene group, phenalenylene group, fluorenylene group, anthraquinolylene group, methylanthrylene group, phenanthrylene group, triphenylenylenealkylphenylene group, C₁-C₁₀ alkoxyphenylene group, halophenylene group, cyanophenylene group, pyrenylene group, chrysenylene group, ethyl- chrysenylene group, picenylene group, perylenylene group, chloroperylenylene group, pentaphenylene group, pentacenyl group, tetraphenylenyl group, hexaphenylene group, hexacenylene group, rubicenylene group, coronenylene group, trinaphthylenylene group, heptaphenylene group, heptacenylene group, pyranthrenylene group, ovalenylene group, carbazolylene group, C₁₋₁₀- alkyl carbazolylene group, thienylene group, indolylene group, purinylene group, benzimidazolylene group, quinolinylene group, benzothiophenylene group, parathiazinylene group, pyrrolylene group, pyrazolylene group, imidazolylene group, imidazolinylene group, oxazolylene group, thiazolylene group, triazolylene group, tetrazolylene group, oxadiazolylene group, pyridinylene group, pyridazinylene group, pyrimidinylene group, pyrazinylene group, thianthrenylene group, pyrrolidinylene group, pyrazolidinylene group, imidazolidinylene group, piperidinylene group, piperazinylene group, and morpholinylene group, but are not limited thereto.

In a soluble compound represented by Formula 1, L₁, L₂, and L₃ are each independently, phenyl group, C₁-C₁₀ alkylphenyl group, C₁-C₁₀alkoxyphenyl group, halophenyl group, cyanophenyl group, dicyanophenyl group, trifluoromethoxyphenyl group, o-, m-, or p-tolyl group, o-, m- or p-cumenyl group, mesityl group, phenoxyphenyl group, (α,α-dimethylbenzene)phenyl group, (N,N′-dimethyl)aminophenyl group, (N,N′-diphenyl)aminophenyl group, (N,N′-bis)methylphenyl))aminophenyl group, (N,N′-dinaphthyl)aminophenyl group, (C₁-C₁₀alkylcyclohexyl)phenyl group, (anthryl)phenyl group, biphenyl group, C₁-C₁₀ alkylbiphenyl group, C₁-C₁₀alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, C₁₋₁₀alkyl carbazolyl group, thienyl group, indolyl group, purinyl group, benzimidazolyl group, quinolinyl group, benzothiophenyl group, parathiazinyl group, pyrrolyl group, pyrazolyl group, imidazolyl group, imidazolinyl group, oxazolyl group, thiazolyl group, triazolyl group, tetrazolyl group, oxadiazolyl group, pyridinyl group, pyridazinyl group, pyrimidinyl group, pyrazinyl group, thianthrenyl group, pyrrolidinyl group, pyrazolidinyl group, imidazolidinyl group, piperidinyl group, piperazinyl group, carbazolyl group, benzoxazolyl group, phenothiazinyl group, 5H-dibenzoazepinyl group, 5H-tribenzoazepinyl group, and morpholinyl group, but are not limited thereto.

In the arylene derivatives represented by Formula 1, L₄ may be hydrogen, methyl group, ethyl group, propyl group, butyl group, methoxy group, ethoxy group, propoxy group, butoxy group, C₁-C₁₀ alkylamine group, C₁-C₁₀ thioalkyl group, phenyl group, C₁-C₁₀ alkylphenyl group, C₁-C₁₀ alkoxyphenyl group, halophenyl group, cyanophenyl group, dicyanophenyl group, trifluoromethoxyphenyl group, o-, m-, or p-tolyl group, o-, m-, or p-cumenyl group, mesityl group, phenoxyphenyl group, (α,α-dimethylbenzene)phenyl group, (N,N′-dimethyl)aminophenyl group, (N,N′-diphenyl)aminophenyl group, (C₁-C₁₀ alkylcyclohexyl)phenyl group, (anthryl)phenyl group, biphenyl group, C₁-C₁₀ alkylbiphenyl group, C₁-C₁₀ alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, cyclopentyl group, cyclohexyl group, C₁-C₁₀ alkylcyclohexyl, or C₁-C₁₀ alkoxycyclohexyl group.

In the arylene derivatives represented by Formula 1, N₁ and N₂ are each independently hydrogen, methyl group, ethyl group, propyl group, butyl group, phenyl group, C₁-C₁₀ alkylphenyl group, C₁-C₁₀ alkoxyphenyl group, halophenyl group, cyanophenyl group, dicyanophenyl group, trifluoromethoxyphenyl group, o-, m-, or p-tolyl group, o-, m-, or p-cumenyl group, mesityl group, phenoxyphenyl group, (α,α-dimethylbenzene)phenyl group, (N,N′-dimethyl)aminophenyl group, (N,N′-diphenyl)aminophenyl group, (C₁-C₁₀ alkylcyclohexyl)phenyl group, (anthryl)phenyl group, biphenyl group, C₁-C₁₀ alkylbiphenyl group, C₁-C₁₀ alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, cyclopentyl group, cyclohexyl group, C₁-C₁₀ alkylcyclohexyl group, or C₁-C₁₀ alkoxycyclohexyl group.

In particular, the arylene derivatives may be represented by Formulas 2 through 16:

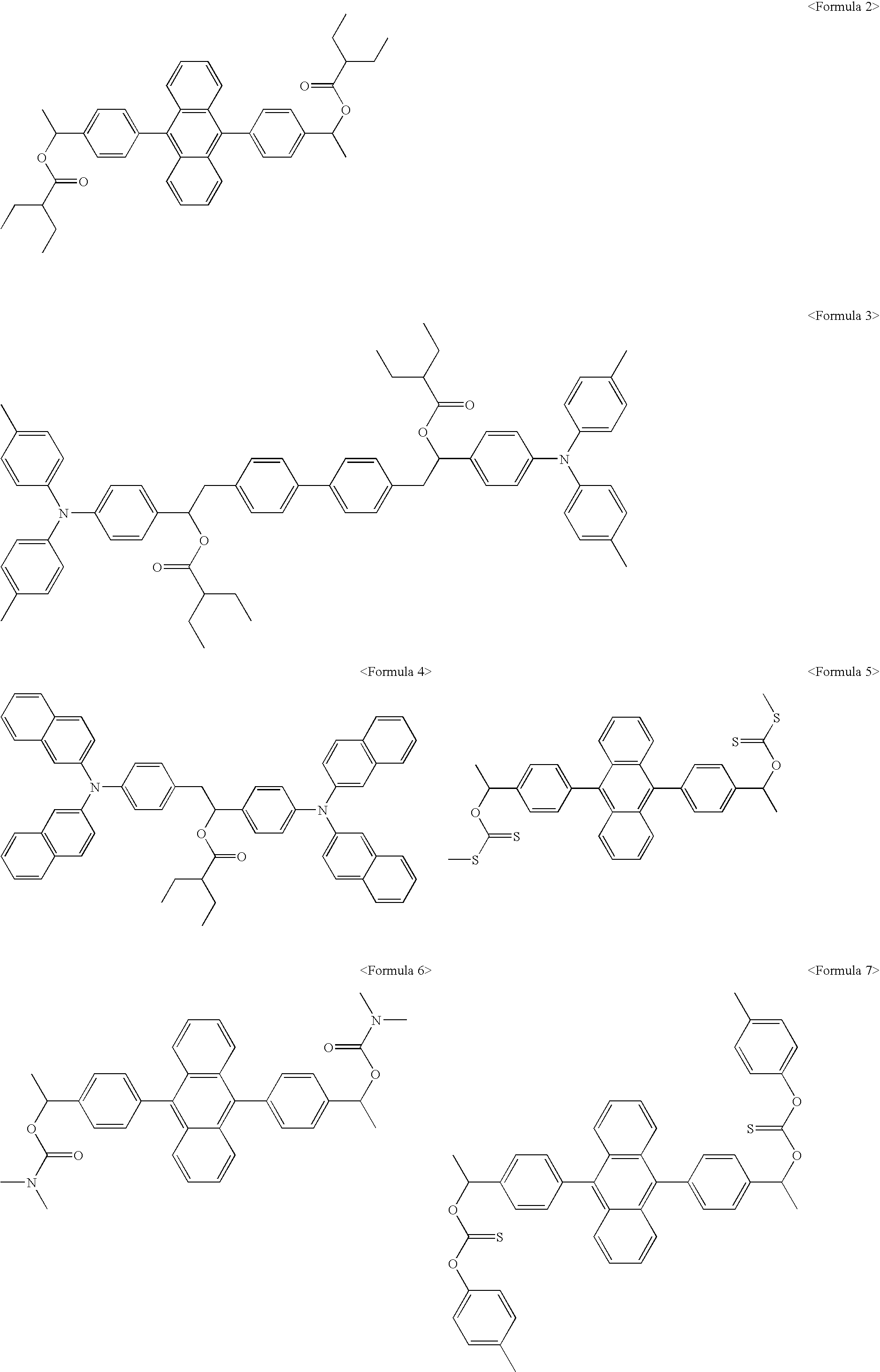

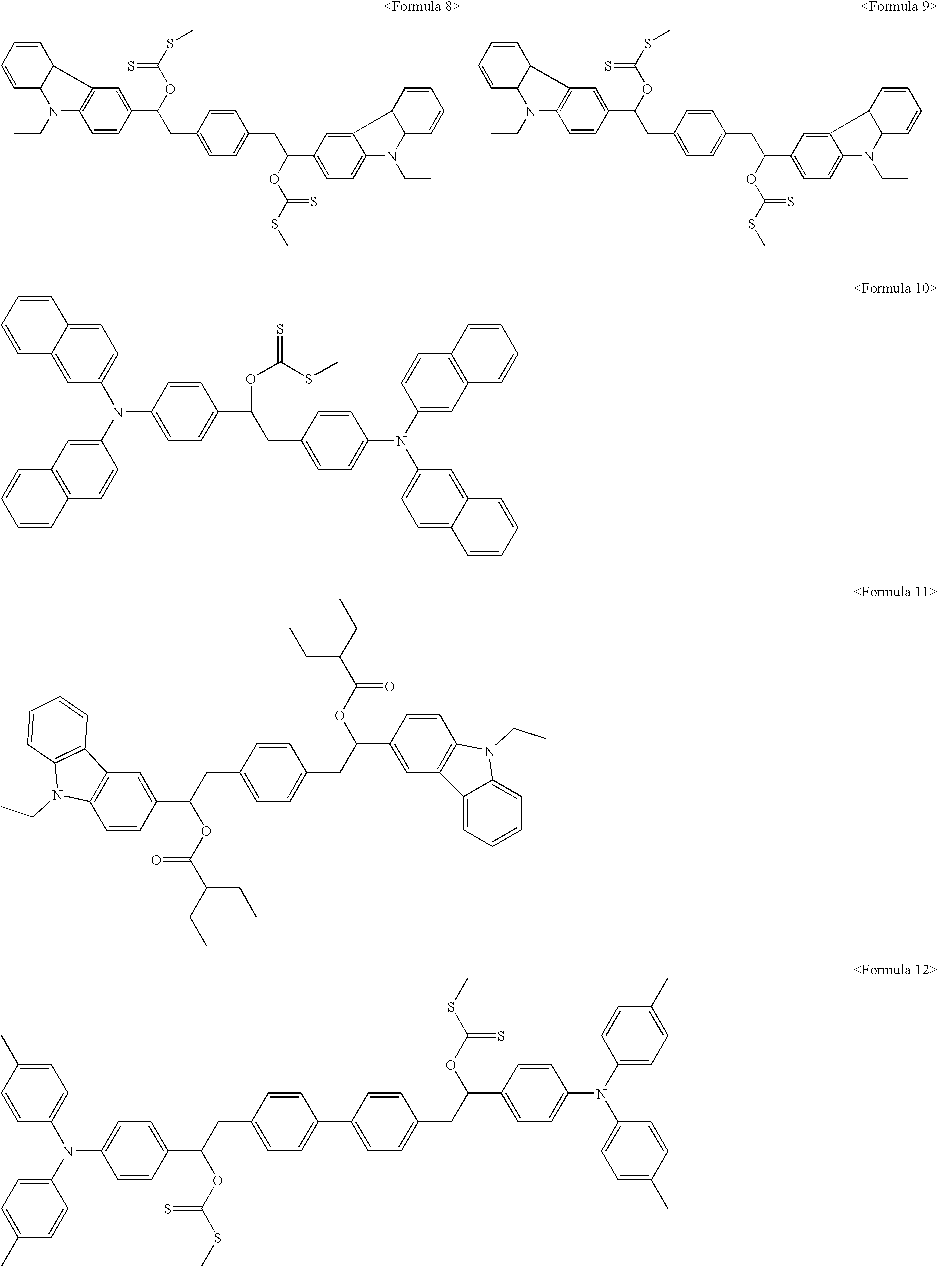

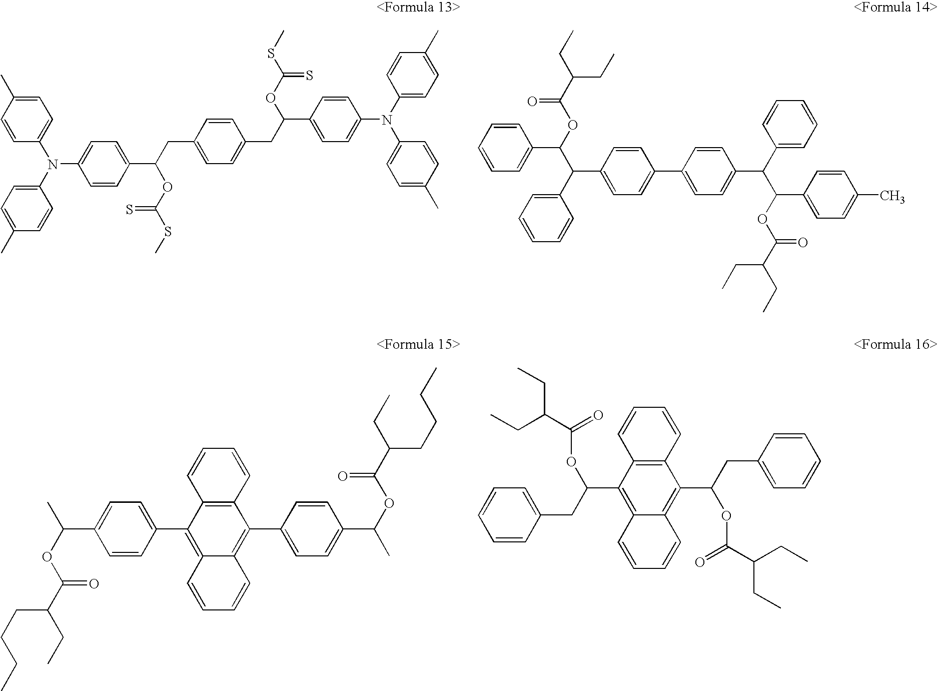

Also, the arylene derivatives may be a soluble compound in which solubility in an organic solvent (20° C.) is more than 0.1% by weight.

An organic light emitting device according to an embodiment of the present invention includes a first electrode, a second electrode, and an organic layer interposed between the first electrode and the second electrode. The organic layer is formed by forming a layer including the arylene derivatives by using a wet method or a laser induced thermal imaging method and thermolyzing the layer.

In the above described device, a polar functional group which exists in the arylene derivative is removed in the thermolysis stage and thus, double bonds are remained. Accordingly, a styryl-based compound exists in the organic layer. When, a light emitting device is manufactured using a conventional vapor deposition method, the properties of the device deteriorates if a styryl-based compound is used (Appl. Phys. Lett, 56(9), 26, February 1990). However, the organic light emitting device according to an embodiment of the present invention shows excellent properties and will be described in detail in Examples below.

In the organic light emitting device, the method of manufacturing the organic layer may be a wet method, for example, spin coating, inkjet printing, spray printing, and heat transferring, but are not limited thereto. Any method used conventionally in the field is available.

The temperature of the thermolysis may be in the range of 100 to 500° C. When the temperature is less than 100° C., a polar functional group of a soluble compound may not be decomposed. When the temperature is above 500° C., a compound itself is decomposed.

The organic light emitting device according to the embodiment of the present invention may have various structures. The device may further include at least one layer interposed between the first electrode and the second electrode selected from the group consisting of a hole injection layer, a hole transport layer, an electron blocking layer, a hole blocking layer, an electron transport layer, and electron injection layer.

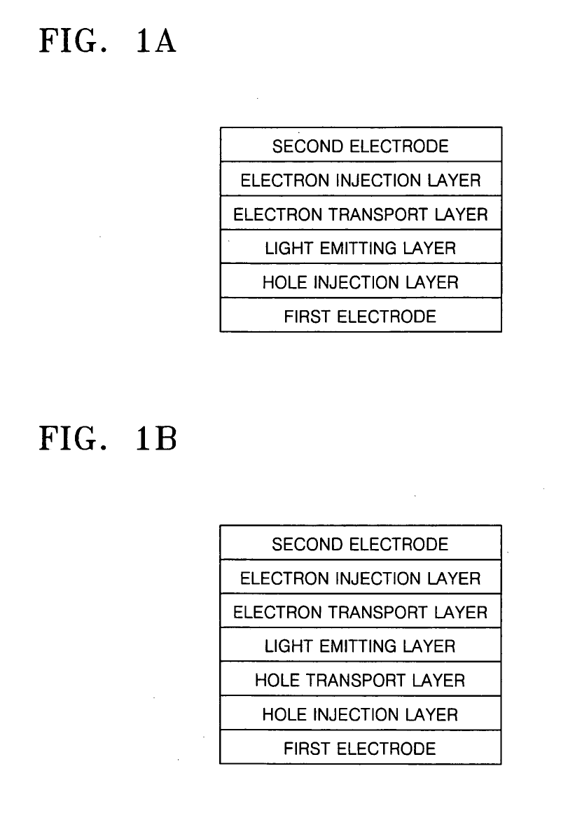

Organic light-emitting devices according to embodiments of the present invention are illustrated in FIGS. 1A, 1B, and 1C. FIG. 1A is a sectional view schematically illustrating an organic light emitting device having a first electrode/hole injection layer/light emitting layer/electron transport layer/electron injection layer/second electrode structure according to an embodiment of the present invention. FIG. 1B is a sectional view schematically illustrating an organic light emitting device having a first electrode/hole injection layer/hole transport layer/light emitting layer/electron transport layer/electron injection layer/second electrode structure according to an embodiment of the present invention. FIG. 1C is a sectional view schematically illustrating an organic light emitting device having a first electrode/hole injection layer/hole transport layer/light emitting layer/hole blocking layer/electron transport layer/electron injection layer/second electrode structure according to an embodiment of the present invention. In these embodiments, the light emitting layer may include a soluble compound according to an embodiment of the present invention.

An emitting layer of an organic light emitting device according to an embodiment of the present invention may contain a phosphorescent or fluorescent dopant which emits red, green, blue, or white light. The phosphorescent dopant may include at least one organometallic compound including an atom selected from Ir, Pt, Os, Ti, Zr, Hf, Eu, Tb, and Tm.

A method of manufacturing an organic light-emitting device according to an embodiment of the present invention will now be described with reference to the organic light-emitting device illustrated in FIG. 1C.

First, a high work function first electrode material is deposited on a substrate using a deposition method or a sputtering method to form a first electrode. The first electrode can be an anode. The substrate may be a substrate that is commonly used in a conventional organic light emitting display device. For example, the substrate may be a glass substrate or a transparent plastic substrate, both of which have mechanical strength, thermal stability, plane surfaces, are transparent, waterproof, and can be easily handled. The first electrode material may be a conductive transparent material, such as indium tin oxide (ITO), indium zinc oxide (IZO), tin oxide (SnO₂), zinc oxide (ZnO), and the like.

Then, a hole injection layer (HIL) can be formed on the first electrode using various methods, such as a vacuum depositing method, a spin coating method, a casting method, a Langmuir-Blodgett (LB) method, or the like.

When the HIL is formed by vacuum deposition, deposition conditions may vary according to HIL forming compounds and the structure and thermal properties of a HIL which is to be formed. For example, a deposition temperature may be in the range of 100 to 500° C., a pressure may be in the range of 10⁻⁸ to 10⁻³ torr, a deposition rate may be in the range of 0.01 to 100 Å/sec, and a thickness of the HIL may be in the range of 10 Å to 5 μm.

When the HIL is formed by spin coating, coating conditions may vary according to HIL forming compounds, the structure and thermal properties of a HIL which will be formed. A coating speed may be in the range of about 2,000 rpm to 5,000 rpm, and a heat treatment temperature for removing a solvent after the coating may be in the range of about 80° C. to 200° C.

The material used to form the HIL is not limited, and may be a phthalocyanine compound, such as copper phthalocyanine disclosed in U.S. Pat. No. 4,356,429; a starburst type amine derivative, such as TCTA, m-MTDATA, and m-MTDAPB, disclosed in Advanced Material, 6, p. 677 (1994); or a conductive soluble polymer, such as polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS).

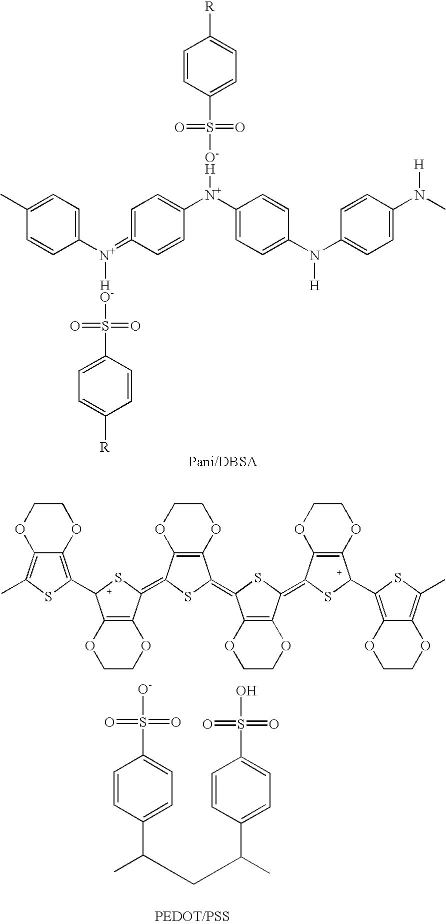

The thickness of the HIL may be in the range of about 100 Å to 10,000 Å, preferably 100 Å to 1,000 Å. When the thickness of the HIL is less than 100 Å, hole injection may deteriorate. When the thickness of the HIL is greater than 10,000 Å, the operating voltage may increase.

Subsequently, a hole transport layer (HTL) can be formed on the HIL by vacuum deposition, spin coating, casting, LB, or the like. When the HTL is formed by vacuum deposition or spin coating, vacuum deposition conditions or spin coating conditions may vary according to HTL forming compounds and may be the same as when the HIL is formed.

The material used to form the HTL is not limited, and may be selected from materials known for forming an HTL. For example, the HTL forming material may be a carbazole derivative, such as N-phenylcarbazole, polyvinylcarbazole, or the like; or a conventional amine derivative having an aromatic condensation ring, such as N,N′-bis(3-methylphenyl)-N,N′-diphenyl-[1,1-biphenyl]-4,4′-diamine(TPD), N,N′-di(naphthalene-1-yl)-N,N′-diphenyl benzidine (α-NPD), or the like.

The thickness of the HTL may be in the range of about 50 to 1,000 Å, for example, 100 Å to 600 Å. When the thickness of the HTL is less than 50 Å, properties of the HTL may deteriorate. When the thickness of the HTL is greater than 1,000 Å, the operating voltage may increase.

Then, a light emitting layer (EML) can be formed on the HTL by vacuum depositing, spin coating, casting, LB, or the like. When the EML is formed by vacuum deposition or spin coating, vacuum deposition conditions or spin coating conditions may vary according to EML forming compounds and may be almost the same as when the HIL is formed.

The EML may be manufactured using the arylene derivatives of Formula 1, as described above. An organic semiconductor may be used together with a soluble compound, for example, pentacene, polythiophene, tetrathiafulvalene, and the like.

The arylene derivatives of Formula 1 can be used together with a proper known host material. The host material may be, for example, tris(8-quinolinolate)aluminum (Alq₃), CBP(4,4′-N,N′-dicarbazole-biphenyl), or PVK(poly(n-vinylcarbazole)).

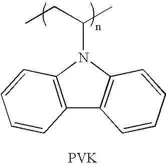

Other dopants, in addition to the aminostyryl compound according to an embodiment of the present invention, can be used to form the EML. For example, a fluorescent dopant can be IDE102 or IDE105 (produced by Idemitsu Kosan Co., Ltd.), or C545T (produced by Hayashibara Inc.); and phosphorescent dopants can be PtOEP or RD 61 (produced by UDC Inc.) as a red phosphorescent dopant, Ir(PPy)₃(PPy=2-phenylpyridine) as a green phosphorescent dopant, and bis[2-(4,6-difluorophenyl)pyridinato-N,C2′] iridium picolinate (F₂Irpic) as a blue phosphorescent dopant.

The concentration of the dopant used is not limited, and may be in the range of 0.01 to 15 parts by weight based on 100 parts by weight of a host.

The thickness of the EML may be in the range of 100 to 1,000 Å, for example, 200 to 600 Å. When the thickness of the EML is less than 100 Å, luminous properties may deteriorate. When the thickness of the EML is greater than 1,000 Å, the operating voltage may increase.

When the EML is formed using a phosphorescent dopant, a hole blocking layer (HBL) can be formed on the HTL using a vacuum deposition method, a spin coating method, a casting method, LB, or the like to prevent diffusion of triple excimers or holes into an electron transport layer. When the HBL is formed by vacuum deposition and spin coating, the vacuum deposition conditions or spin coating conditions may vary according to HBL forming compounds and may be almost the same as when the HIL is formed. A known, available hole blocking material can be, for example, an oxadiazole derivative, a triazole derivative, a phenanthroline derivative, a hole blocking material disclosed in JP 11-329734(A1), BCP, or the like.

The thickness of the HBL may be in the range of about 50 to 1,000 Å, for example, 100 to 300 Å. When the thickness of the HBL is less than 50 Å, a hole blocking property may decrease. On the other hand, when the thickness of the HBL is greater than 1,000 Å, the operating voltage may increase.

Subsequently, an electron transport layer (ETL) can be formed using a vacuum deposition method, a spin coating method, a casting method, or the like. When the ETL is formed by vacuum deposition or spin coating, the vacuum deposition conditions or spin coating conditions may vary according to ETL forming compounds and may be almost the same as when the HIL is formed. The compound used to form the ETL stably transports electrons injected from an electron injection electrode (cathode) and can be a quinoline derivative, such as tris(8-quinolinolate)aluminum (Alq₃) or TAZ.

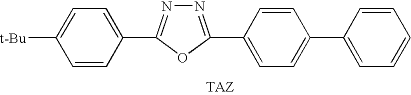

The thickness of the ETL may be in the range of about 100 to 1,000 Å, for example, 200 to 500 Å. When the thickness of the ETL is less than 100 Å, electron transportation may be degraded. When the thickness of the ETL is greater than 1,000 Å, the operating voltage may increase.

An electron injection layer (EIL), which allows easy injection of electrons from a cathode, can be formed on the ETL. Material used to form the EIL is not particularly restricted.

The EIL can be formed of any known EIL forming material, such as LiF, NaCl, CsF, Li₂O, BaO, or the like. Conditions for depositing an EIL may vary according to the materials used to form the EIL and may be almost the same as when the HIL is formed.

The thickness of the EIL may be in the range of about 1 to 100 Å, for example, 5 to 50 Å. When the thickness of the EIL is less than 1 Å, electron injection may be degraded. When the thickness of the EIL is greater than 100 Å, the operating voltage may increase.

Subsequently, a second electrode can be formed on the EIL using a vacuum deposition method or a sputtering method. The second electrode can be used as a cathode. The material used to form the second electrode can be a metal, an alloy, an electrically conductive compound, or a mixture of these, which has a low work function. For example, the material used to form the second electrode is Li, Mg, Al, Al—Li, Ca, Mg—In, Mg—Ag, or the like. Alternatively, in order to obtain a front emission type light-emitting device, the cathode can be formed of a transparent material, such as ITO or IZO.

An organic light-emitting device according to an embodiment of the present invention may have various structures, in addition to the structure of an organic light-emitting device including a first electrode, a HIL, a HTL, an EML, a HBL, an ETL, an EIL, and a second electrode illustrated in FIG. 1C. For example, the organic light-emitting device according to an embodiment of the present invention can be an organic light-emitting device having the structure illustrated in FIG. 1A, which will be described in detail in Examples below. In addition, a number of layers described above may be excluded, if needed.

A manufacturing method of an organic light emitting device according to an embodiment of the present invention includes forming an organic layer in which the arylene derivative is included by using a wet method or a laser induced thermal imaging method and thermolyzing the organic layer.

When the method described above is used, a polar functional group of the arylene derivative is decomposed in the thermolysis stage and evaporated and thus, a styryl-based compound including a vinyl group exists in the device.

In the method of manufacturing the organic light emitting device, the wet method includes spin coating, inkjet printing, spray printing, and heat transferring but is not limited thereto.

The temperature of the thermolysis may be in the range of 100 to 500° C. When the temperature is less than 100° C., a polar functional group of the arylene derivative may not be decomposed. When the temperature is above 500° C., the arylene derivative compound itself is decomposed.

The arylene derivative of formula 1 was prepared according to a conventional organic synthesis method. Synthesis products were determined using 1H NMR, and Mass Spectrometer.

Hereinafter, Synthesis Examples and Examples for preparing Compounds 2, 5, and 15 respectively represented by formulae 2, 5, and 15 (hereinafter, referred to as “Compound 2”, “Compound 5”, and “Compound 15”) according to embodiments of the present invention will be described in detail.

The present invention will be described in greater detail with reference to the following examples. The following examples are for illustrative purposes and are not intended to limit the scope of the invention.

### SYNTHESIS EXAMPLE

### Synthesis Example 1

### Synthesis of Intermediate A

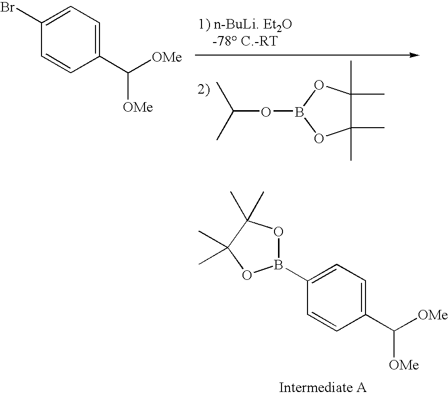

2.3 g (10 mmol) of 4- bromo benzaldehyde dimethylacetal was dissolved in 100 ml of tetrahydrofuran (THF) and the temperature was reduced to −78° C., then, 4.0 ml (10.0 mmol) of 2.5M n-BuLi was gradually added thereto. The mixture was reacted for 1 hour. Then, 1.86 g (10 mmol) of 2-isopropoxy-4,4,5,5-tetramethyl-1,3,2-dioxaborolane was added to be reacted for 1 hour and then, the temperature was raised to room temperature and stirred for 24 hours.

The reaction was completed by adding water to the mixture. Then 300 ml of chloroform was added and washed with 200 ml of water. An organic layer was dried using anhydride magnesium sulfate.

2.5 g of Intermediate A (Yield: 92%) was obtained using silica chromatography.

### Synthesis Example 2

### Synthesis of Intermediate B

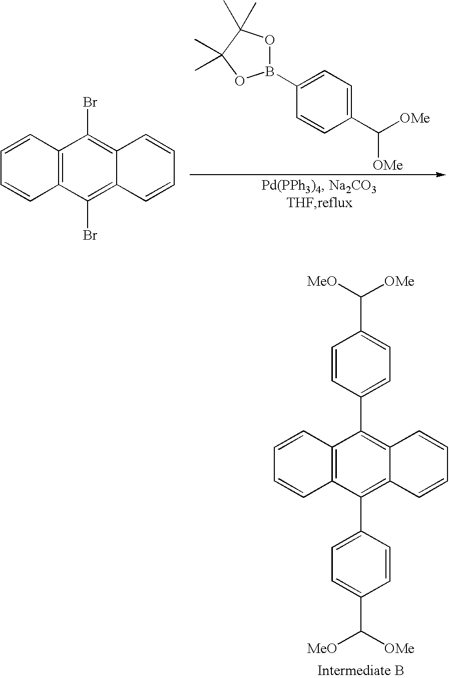

1 g (3 mmol) of 9,10- dibromo anthracene was dissolved in 30 ml of THF and 5.6 g (6 mmol) of Intermediate A, 173 mg (0.15 mmol) of tetrakis triphenylphosphin palladium (Pd(PPh₃)₄) were dissolved in the mixture, and 636 mg (6 mmol) of sodium carbonate (Na₂CO₃) in 30 ml of toluene and 5 ml of water were added to reflux for 24 hours. After the reaction is completed, solvent was removed by evaporation and 100 ml of ethyl acetate was added. Then, the resultant was washed with 100 ml of water and the organic layer was collected and dried with anhydride magnesium sulfate. 1.04 g of Intermediate B (Yield: 73%) was obtained using silica chromatography.

### Synthesis Example 3

### Synthesis of Intermediate C

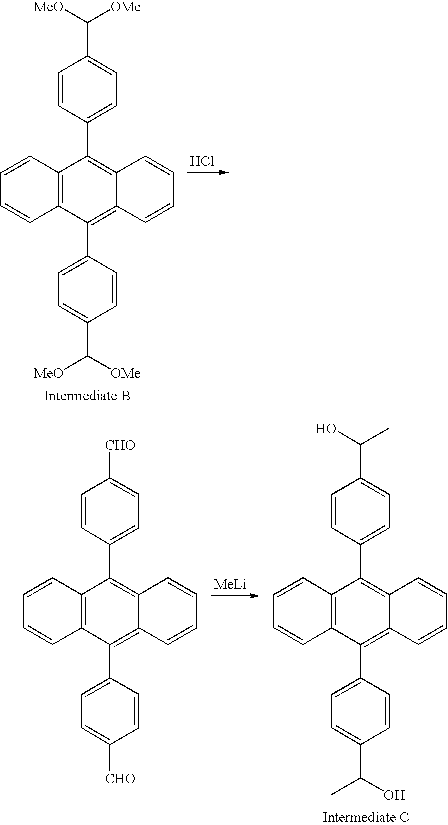

HCl was added to 480 mg (1 mmol) of Intermediate B and stirred for 1 hour. After the reaction was completed, the obtained solid was filtered and dried. 385 mg (1 mmol) of the dried solid aldehyde compound was dissolved in 10 ml of anhydrous THF, then cooled down to −78° C. and 1.5 ml (1.6 M solution in diethyl ether) of methyl lithium (MeLi) was gradually added and the mixture was stirred for 3 hours. When the reaction was completed, the reactant mixture was extracted 3 times using saturated aqueous ammonium chloride (NH₄Cl) solution and ethyl acetate, dried with anhydride magnesium sulfate, and concentrated under reduced pressure. Then, 252 mg of Intermediate C (Yield: 61%) was obtained using silica chromatography.

¹H-NMR (CDCl₃, 300 MHz): 7.70 (q, 4H), 7.66 (d, 4H), 7.47 (d, 4H), 7.33 (q, 4H), 5.11 (q,2H), 1.69 (d, 6H), 1.60 (s, 2H).

### Examples

### Example 1

### Synthesis of Compound 2 Represented by Formula 2

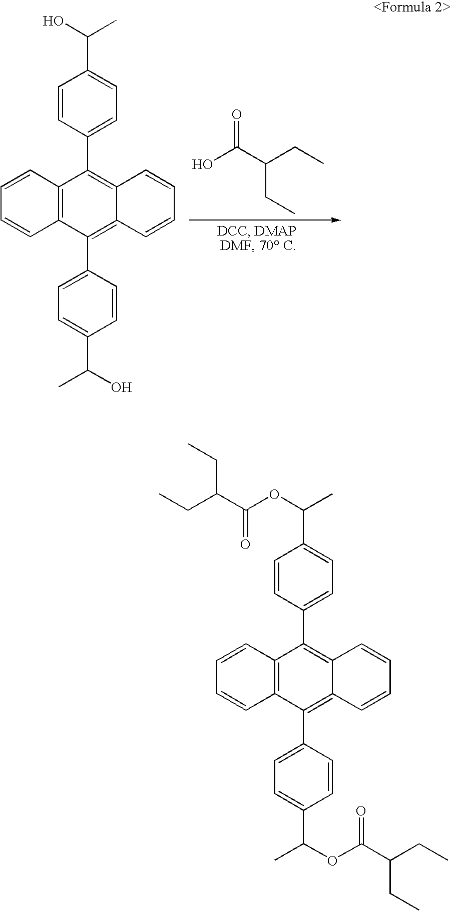

After dissolving 700 mg (1.7 mmol) of Intermediate C and 4.2 ml (33.4 mmol) of 2-Ethylbutyric acid in 20 ml of dimethylformamide (DMF), 3.4 g (16.7 mmol) of N,N-dicyclohexylcarbodiimide (hereinafter, referred to as DCC) and 204 mg (1.67 mmol) of 4-dimethylaminopyridine (hereinafter, referred to as DMAP) were added to the resultant. Then, the reaction temperature was raised to 70° C. and the mixture was stirred for 24 hours. When the reaction was completed, the solvent was removed by evaporation and 50 ml of ethyl acetate was added. Then, the reactant resultant was washed 2 times and the organic layer was collected and dried with anhydride magnesium sulfate.

812 mg of compound 2 (Yield: 79%) was obtained using silica chromatography.

¹H-NMR (CDCl₃, 300 MHz): 7.65 (q, 4H), 7.59 (d, 4H), 7.44 (d, 4H), 7.30 (q, 4H), 6.11 (q,2H), 2.31-2.29 (m, 2H), 1.73-1.52 (m, 14H), 0.97-0.87 (m, 12H).

### Example 2

### Synthesis of Compound 5 Represented by Formula 5

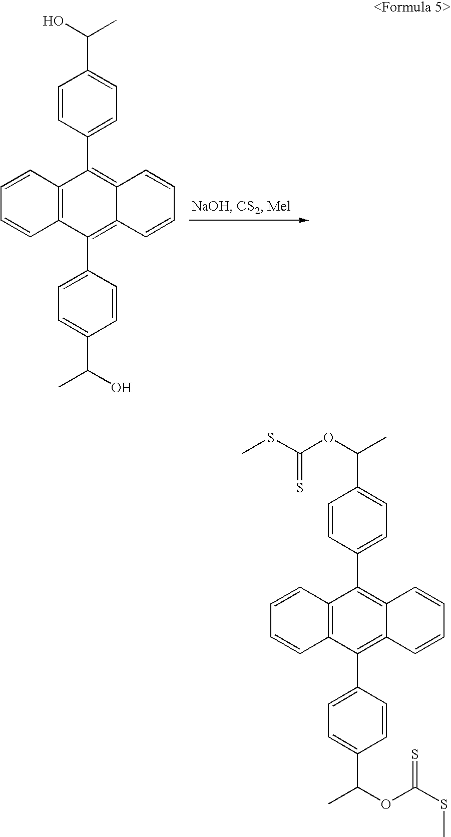

After dissolving 421 mg (1 mmol) of Intermediate C in 50 ml of diethylether and 0.5 ml of carbon tetrachloride, 160 mg (4 mmol) of NaOH and 300 mg (4 mmol) of carbon disulfide (CS₂) were added thereto and stirred for 1 hour. Then, 300 mg (2.1 mmol) of methyl iodide (MeI) was gradually added and stirred for 96 hours.

When the reaction was completed, the reaction mixture was diluted with 50 ml of ethyl acetate and washed with diluted hydrochloric acid, diluted sodium hydrogen carbonate, and 50 ml of water. Then, the organic layer was collected and dried with anhydride magnesium sulfate, and concentrated under reduced pressure. 301 mg of compound 5 (Yield: 49%) was obtained using a silica chromatography.

¹H-NMR (CDCl₃, 300 MHz): 7.66 (q, 4H), 7.60 (d, 4H), 7.45 (d, 4H), 7.31 (q, 4H), 4.68 (q,2H), 2.00 (d, 6H), 1.49 (d, 6H).

### Example 3

### Synthesis of Compound 15 Represented by Formula 15

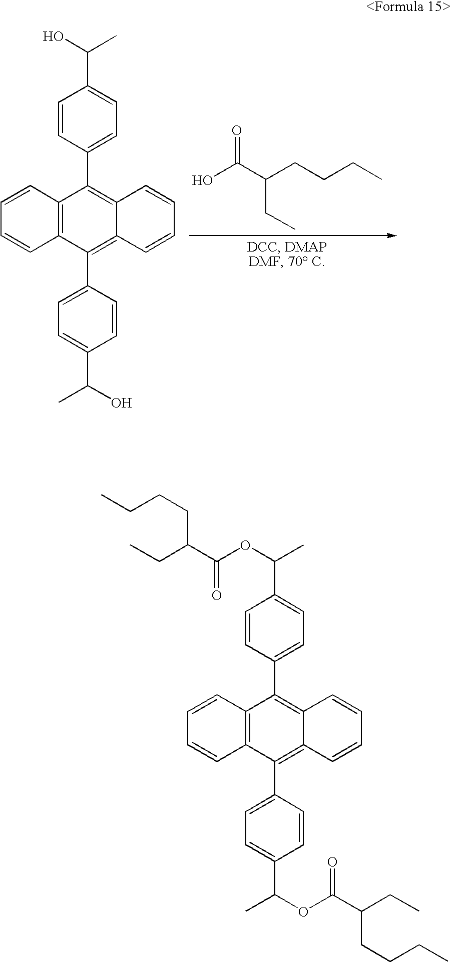

After dissolving 418 mg (1.0 mmol) of Intermediate C and 2.9 ml (20 mmol) of 2-Ethylhexanoic acid in 12 ml of DMF, then 2.1 g (10 mmol) of DCC and 122 mg (1 mmol) of DMAP were added thereto and the reaction temperature was raised to 70° C. and stirred for 24 hours. After the reaction was completed, the solvent was removed by evaporation and 50 ml of ethyl acetate was added. Then, the resultant was washed twice with 50 ml of water and the organic layer was collected and dried with anhydride magnesium sulfate. 812 mg of compound 15 (Yield: 79%) was obtained using a silica chromatography.

¹H-NMR (CDCl₃, 300 MHz): 7.64 (q, 4H), 7.59 (d, 4H), 7.44 (d, 4H), 7.29 (q, 4H), 6.12 (q,2H), 2.33-2.29 (m, 2H), 1.75-1.51 (m, 14H), 0.97-0.86 (m, 20H).

### Evaluation Example 1

### Luminous Properties of Compounds 2

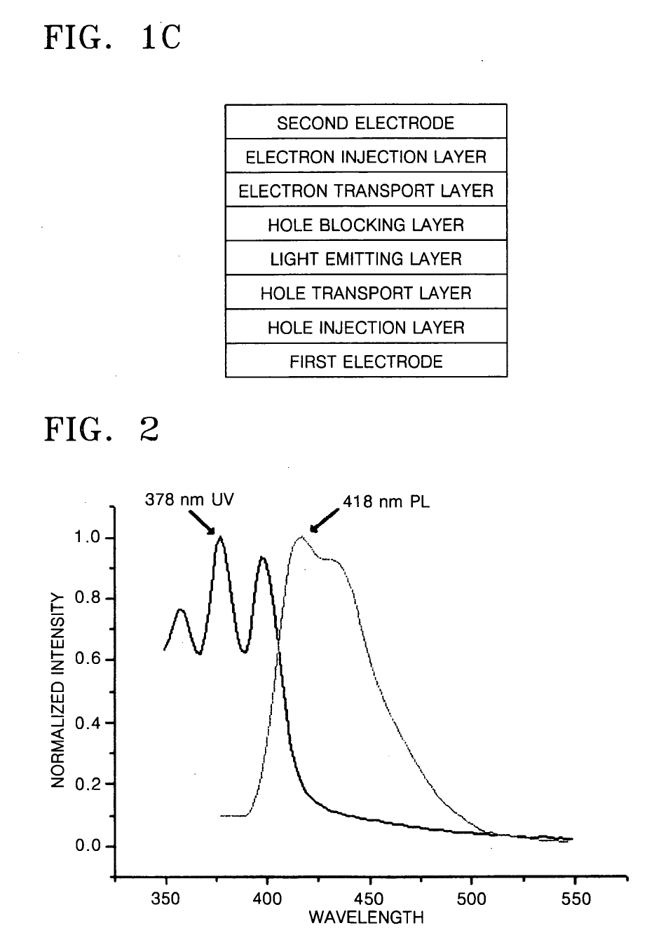

Absorption spectra and photoluminescence (PL) spectra of compounds 2 was measured to determine luminous properties thereof. First, Compound 2 was diluted using toluene to have a concentration of 0.2 mM, and an absorption spectrum of compound 2 was recorded using a Shimadzu UV-350 spectrometer. Meanwhile, compound 2 was diluted using toluene to have a concentration of 10 mM, and a PL spectrum of compound 2 was recorded using an ISC PC1 spectrofluorometer including a Xenon lamp. The same experiments were performed on compounds 5 and 15. The results are shown in Table 1 and FIG. 2:

TABLE 1

| | Maximum Absorption | Maximum PL |
|---|---|---|
| Compound No | Wavelength (nm) | Wavelength (nm) |
| 2 | 378 | 418 |
| 5 | 380 | 420 |
| 15 | 378 | 418 |

### Evaluation Example 2

### Confirming Polar Functional Group Removal TGA (Thermogravimetric Analysis) Experiment

In order to identify whether an ester group of the compound 2 was removed or not, a TGA experiment was conducted using an Instrument TGA 2050.

A thermal property of compound 2 was measured by raising the temperature from room temperature to 600° C. at a rate of 10° C./min in a nitrogen atmosphere.

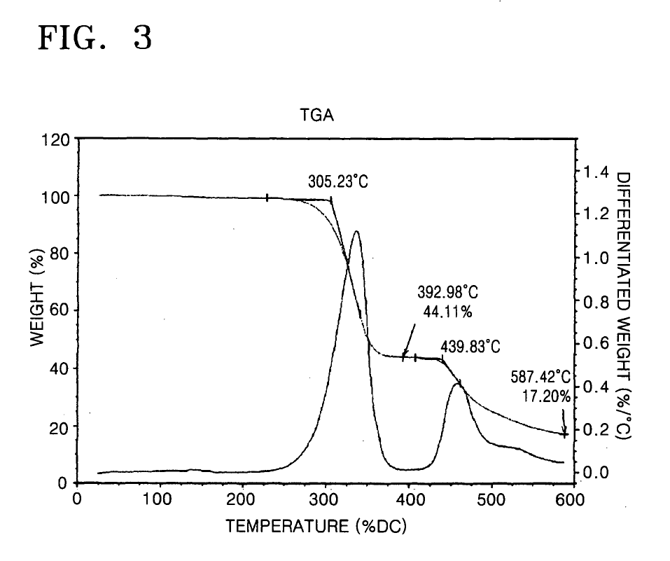

The result is shown in FIG. 3.

As illustrated in FIG. 3, sudden weight change occurs around the temperature of 300° C. and it is determined that the ester group had been removed.

IR (Infrared) Experiment

In order to identify whether an ester group of the compound 2 had been removed or not, an IR experiment is conducted before and after heat treatment.

IR changes of the layer before and after the heat treatment were measured using a Bio-Rad Excalibur Series IR spectrometer.

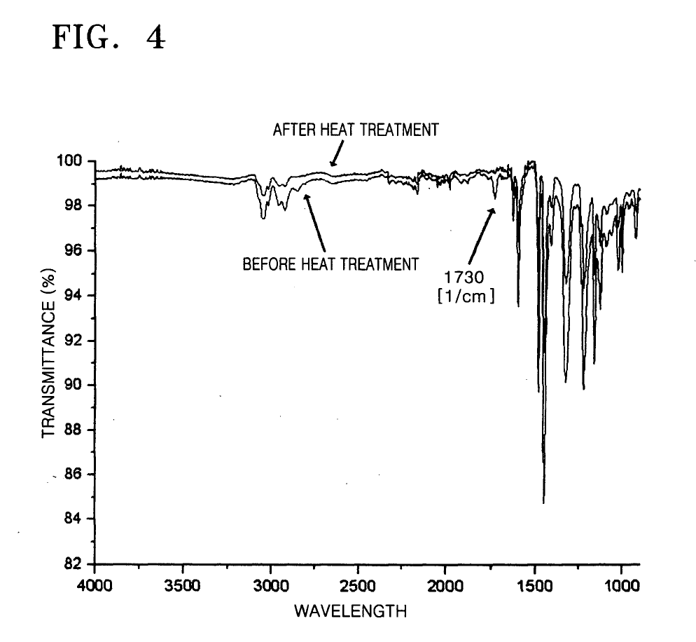

The result is shown in FIG. 4.

As illustrated in FIG. 4, after the heat treatment, an ester peak at 1730 cm⁻¹ has disappeared. Therefore, it is determined that the ester group is removed by the heat treatment.

### Evaluation Example 3

### Device Properties of Samples

An organic light emitting device was manufactured using compound 2 as a dopant of a light emitting layer (EML). The organic light emitting device was manufactured having the structure of ITO/PEDOT(50 nm)/pentacene_compound 2(50 nm)/Alq3(20 nm)/LiF(1 nm)/Al(200 nm).

In order to prepare an anode, an ITO glass substrate 15 Ω/cm² (1200 Å) produced by Corning Inc. was cut to a size of 50 mm×50 mm×0.7 mm, sonicated using isopropyl alcohol and pure water for 5 minutes, and washed using ultra violet (UV) ozone for 30 minutes. Then, PEDOT-PSS (Al4083) produced by Bayer Inc. was coated on the substrate and heat treated at 120° C. for 5 hours to form a HIL having a thickness of 500 Å. A mixture of 2 g of dichlorobenzene solution of pentacene (0.05% by weight) and 0.01 g of compound 2 (10 parts by weight of compound 2 based on 100 parts by weight of pentacene) was spin coated on the HIL and then heat treated at 110° C. for 2 hours to form an EML having a thickness of 50 nm. Then, an Alq3 compound was vacuum deposited to a thickness of 20 nm to form an ETL. Then, LiF was vacuum deposited on the ETL to form an EIL having a thickness of 10 Åand then, Al was vacuum deposited on the EIL to form a cathode having a thickness of 2,000 Å. As a result, an organic light emitting device having the structure illustrated by FIG. 1A was completely manufactured. The obtained organic light emitting device will be referred to as Sample 2.

Organic light emitting devices were manufactured using compounds 5 and 15 in the same manner as in the method described above. The obtained organic light emitting devices will be referred to as Samples 5 and 15.

Operating voltages, brightness, and efficiencies of Samples 2, 5, and 15 were measured using a PR650 (Spectroscan) Source Measurement Unit. The results are shown in Table 4.

TABLE 4

| | Operating | Brightness | Efficiency |
|---|---|---|---|
| Sample No | Voltage (V) | (cd/m2) | (cd/A) |
| 2 | 7 | 740 | 0.24 |
| 5 | 7.2 | 490 | 0.15 |
| 15 | 7.4 | 680 | 0.21 |

As shown in Table 2, Samples 2, 5, and 15 according to embodiments of the present invention have excellent properties.

A soluble compound including a polar functional group according to the embodiments of the present invention has excellent solubility in an organic solvent. Accordingly, a thermally stable organic layer can be formed. An organic light emitting device using the soluble compound and has low operating voltage, high efficiency, and excellent brightness.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An arylene derivative represented by Formula 1: 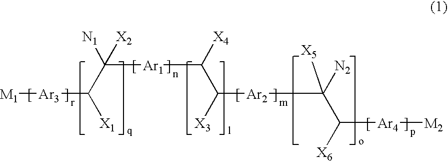
where Ar₁, Ar₂, Ar₃, and Ar₄ are each independently a substituted or unsubstituted C₆-C₃₀ arylene group, or a substituted or unsubstituted C₂-C₃₀ heteroarylene group;
M₁ and M₂ are each independently hydrogen, 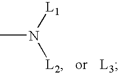
L₁, L₂, and L₃ are each independently a substituted or unsubstituted C₆-C₃₀ aryl group or a substituted or unsubstituted C₂-C₃₀ heteroaryl group; L₁ and L₂ may be connected to form a substituted or unsubstituted ring with the N atom;
N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;
at least one of X₁ and X₂, X₃ and X₄, and X₅ and X₆ are 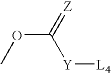
where Y is sulfur, carbon, nitrogen, or oxygen, Z is sulfur or oxygen, L₄ is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, a substituted or unsubstituted C₂-C₃₀ heteroaryl group, an alkoxy group, an alkylamine group, or a thioalkyl group;
l, o and q are each integers of 0 or 1;
1+o+q is an integer of 1 through 3; and
m, n, p and r are each integers of 0 through 3.

2. The arylene derivative of claim 1, wherein the compound represented by Formula 1 is the compound represented by Formula 1a: 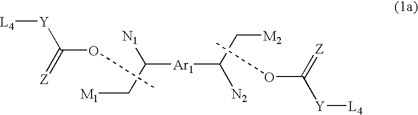
where Ar₁, M₁, M₂, N₁, N₂, L₄, Y, and Z are defined as in claim 1.

3. The arylene derivative of claim 1, wherein the compound represented by Formula 1 is a compound represented by Formula 1b: 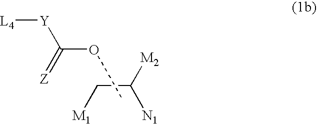
where M₁, M₂, N₁, L₄, Y, and Z are defined as in claim 1.

4. The arylene derivative of claim 1, wherein Ar₁, Ar₂, Ar₃, and Ar₄ are each independently, a substituted or unsubstituted phenylene group, a substituted or unsubstituted naphthalene group, a substituted or unsubstituted anthracene group, a substituted or unsubstituted phenanthrene group, a substituted or unsubstituted fluorene group, a substituted or unsubstituted carbazoyl group, a substituted or unsubstituted thiophene group, or a substituted or unsubstituted thiazole group;
N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;
M₁ and M₂ are each independently, hydrogen, 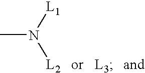
L₁, L₂, and L₃ are each independently, a substituted or unsubstituted phenyl group, a substituted or unsubstituted naphthalene group, a substituted or unsubstituted anthracene group, or a substituted or unsubstituted phenanthrene group; L₁ and L₂ may be connected each other to form a substituted or unsubstituted ring with the N atom.

5. The arylene derivative of claim 1, wherein the substituents of the alkyl group, the aryl group, the heteroaryl group, and the cycloalkyl group are at least one selected from the group consisting of —F, —Cl, —Br, —CN, —NO₂ or —OH; a C₁-C₂₀ alkyl group unsubstituted or substituted for —F, —Cl, —Br, —CN, —NO₂, or —OH; a C₁-C₂₀ alkoxy group unsubstituted or substituted for —F, —Cl, —Br, —CN, —NO₂, or —OH; a C₆-C₃₀ aryl group unsubstituted or substituted for —F, —Cl, —Br, —CN, —NO₂, or —OH; a C₂-C₃₀ heteroaryl group unsubstituted or substituted for —F, —Cl, —Br, —CN, —NO₂, or —OH; and
a C₅-C₂₀cycloalkyl group unsubstituted or substituted for —F, —Cl, —Br, —CN, —NO₂, or —OH.

6. The arylene derivative of claim 1, wherein Ar₁, Ar₂, Ar₃, and Ar₄ are each independently selected from the group consisting of phenylene group, C₁-C₁₀ dicyanophenylene group, trifluoromethoxyphenylene group, o-, m-, or p-tolylene group, o-, m-, or p-cumenylene group, mesitylene group, phenoxyphenylene group, (α,α-dimethylbenzene)phenylene group, (N,N′-dimethyl)aminophenylene group, (N,N′-diphenyl)aminophenylene group, (C₁-C₁₀alkylcyclohexyl)phenylene group, (anthryl)phenylene group, biphenylene group, C₁-C₁₀alkylbiphenylene group, C₁-C₁₀ alkoxybiphenylene group, pentalenyl group, indenylene group, naphthylene group, C₁-C₁₀ alkylnaphthylene group, C₁-C₁₀ alkoxynaphthylene group, halonaphthylene group, cyanonaphthylene group, biphenylenylene group, C₁-C₁₀ alkyl biphenylenylene group, C₁-C₁₀ alkoxy biphenylenylene group, anthrylene group, biphenylanthrylene group, azulenylene group, heptalenylene group, acenaphthylenylene group, phenalenylene group, fluorenylene group, anthraquinolylene group, methylanthrylene group, phenanthrylene group, triphenylenylenealkylphenylene group, C₁-C₁₀ alkoxyphenylene group, halophenylene group, cyanophenylene group, pyrenylene group, chrysenylene group, ethyl- chrysenylene group, picenylene group, perylenylene group, chloroperylenylene group, pentaphenylene group, pentacenyl group, tetraphenylenyl group, hexaphenylene group, hexacenylene group, rubicenylene group, coronenylene group, trinaphthylenylene group, heptaphenylene group, heptacenylene group, pyranthrenylene group, ovalenylene group, carbazolylene group, C₁₋₁₀ alkyl carbazolylene group, thienylene group, indolylene group, purinylene group, benzimidazolylene group, quinolinylene group, benzothiophenylene group, parathiazinylene group, pyrrolylene group, pyrazolylene group, imidazolylene group, imidazolinylene group, oxazolylene group, thiazolylene group, triazolylene group, tetrazolylene group, oxadiazolylene group, pyridinylene group, pyridazinylene group, pyrimidinylene group, pyrazinylene group, thianthrenylene group, pyrrolidinylene group, pyrazolidinylene group, imidazolidinylene group, piperidinylene group, piperazinylene group, and morpholinylene group.

7. The arylene derivative of claim 1, wherein L₁, L₂, and L₃ are each independently selected from the group consisting of phenyl group, C₁-C₁₀ alkylphenyl group, C₁-C₁₀ alkoxyphenyl group, halophenyl group, cyanophenyl group, dicyanophenyl group, trifluoromethoxyphenyl group, o-, m-, or p-tolyl group, o-, m- or p-cumenyl group, mesityl group, phenoxyphenyl group, (α,α-dimethylbenzene)phenyl group, (N,N′-dimethyl)aminophenyl group, (N,N′-diphenyl)aminophenyl group, (N,N′-bis)methylphenyl))aminophenyl group, (N,N′-dinaphthyl)aminophenyl group, (C₁-C₁₀ alkylcyclohexyl)phenyl group, (anthryl)phenyl group, biphenyl group, C₁-C₁₀ alkylbiphenyl group, C₁-C₁₀alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, C₁₋₁₀alkyl carbazolyl group, thienyl group, indolyl group, purinyl group, benzimidazolyl group, quinolinyl group, benzothiophenyl group, parathiazinyl group, pyrrolyl group, pyrazolyl group, imidazolyl group, imidazolinyl group, oxazolyl group, thiazolyl group, triazolyl group, tetrazolyl group, oxadiazolyl group, pyridinyl group, pyridazinyl group, pyrimidinyl group, pyrazinyl group, thianthrenyl group, pyrrolidinyl group, pyrazolidinyl group, imidazolidinyl group, piperidinyl group, piperazinyl group, carbazolyl group, benzoxazolyl group, phenothiazinyl group, 5H-dibenzoazepinyl group, 5H-tribenzoazepinyl group, and morpholinyl group.

8. The arylene derivative of claim 1, wherein L₄ is selected from the group consisting of hydrogen, methyl group, ethyl group, propyl group, butyl group, methoxy group, ethoxy group, propoxy group, butoxy group, C₁-C₁₀alkylamine group, C₁-C₁₀ thioalkyl group, phenyl group, C₁-C₁₀alkylphenyl group, C₁-C₁₀alkoxyphenyl group, halophenyl group, cyanophenyl group, dicyanophenyl group, trifluoromethoxyphenyl group, o-, m-, or p-tolyl group, o-, m-, or p-cumenyl group, mesityl group, phenoxyphenyl group, (α,α-dimethylbenzene)phenyl group, (N,N′-dimethyl)aminophenyl group, (N,N′-diphenyl)aminophenyl group, (C₁-C₁₀ alkylcyclohexyl)phenyl group, (anthryl)phenyl group, biphenyl group, C₁-C₁₀ alkylbiphenyl group, C₁-C₁₀ alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, cyclopentyl group, cyclohexyl group, C₁-C₁₀ alkylcyclohexyl, and C₁-C₁₀alkoxycyclohexyl group.

9. The arylene derivative of claim 1, wherein N₁ and N₂ are each independently selected from the group consisting of hydrogen, methyl group, ethyl group, propyl group, butyl group, phenyl group, C₁-C₁₀ alkylphenyl group, C₁-C₁₀ alkoxyphenyl group, halophenyl group, cyanophenyl group, dicyanophenyl group, trifluoromethoxyphenyl group, o-, m-, or p-tolyl group, o-, m-, or p-cumenyl group, mesityl group, phenoxyphenyl group, (α,α-dimethylbenzene)phenyl group, (N,N′-dimethyl)aminophenyl group, (N,N′-diphenyl)aminophenyl group, (C₁-C₁₀ alkylcyclohexyl)phenyl group, (anthryl)phenyl group, biphenyl group, C₁-C₁₀ alkylbiphenyl group, C₁-C₁₀ alkoxybiphenyl group, pentalenyl group, indenyl group, naphthyl group, C₁-C₁₀ alkylnaphthyl group, C₁-C₁₀ alkoxynaphthyl group, halonaphthyl group, cyanonaphthyl group, biphenylenyl group, C₁-C₁₀ alkyl biphenylenyl group, C₁-C₁₀ alkoxy biphenylenyl group, anthracenyl group, azulenyl group, heptalenyl group, acenaphthylenyl group, phenalenyl group, fluorenyl group, anthraquinolyl group, methylanthryl group, phenanthryl group, triphenylenyl group, pyrenyl group, chrysenyl group, ethyl-chrysenyl group, picenyl group, perylenyl group, chloroperylenyl group, pentaphenyl group, pentacenyl group, tetraphenylenyl group, hexaphenyl group, hexacenyl group, rubicenyl group, coronenyl group, trinaphthylenyl group, heptaphenyl group, heptacenyl group, pyranthrenyl group, ovalenyl group, carbazolyl group, cyclopentyl group, cyclohexyl group, C₁-C₁₀ alkylcyclohexyl group, and C₁-C₁₀alkoxycyclohexyl group.

10. The arylene derivative of claim 1, wherein the arylene derivative is represented by one of Formulas 2 through 16:

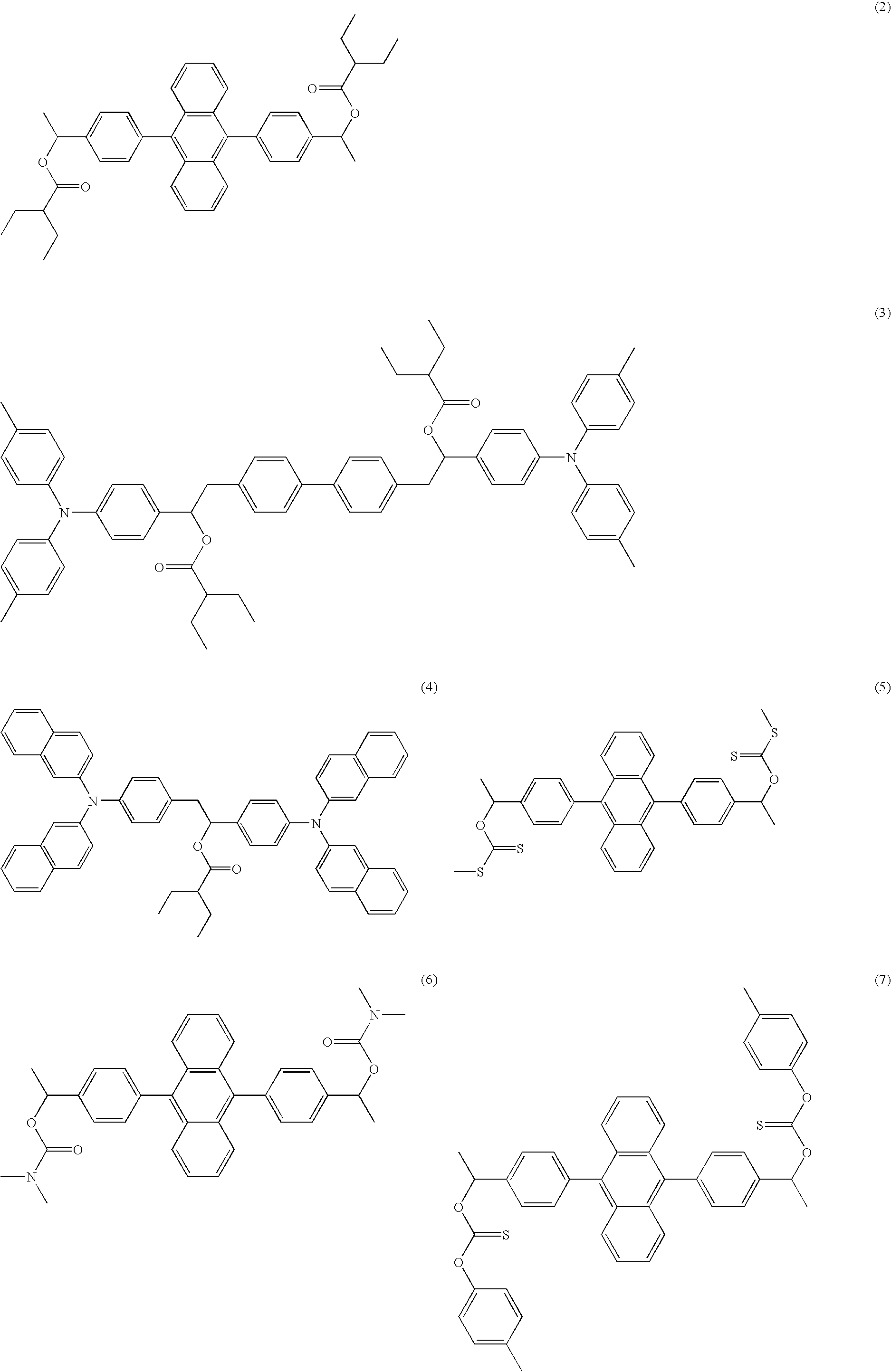

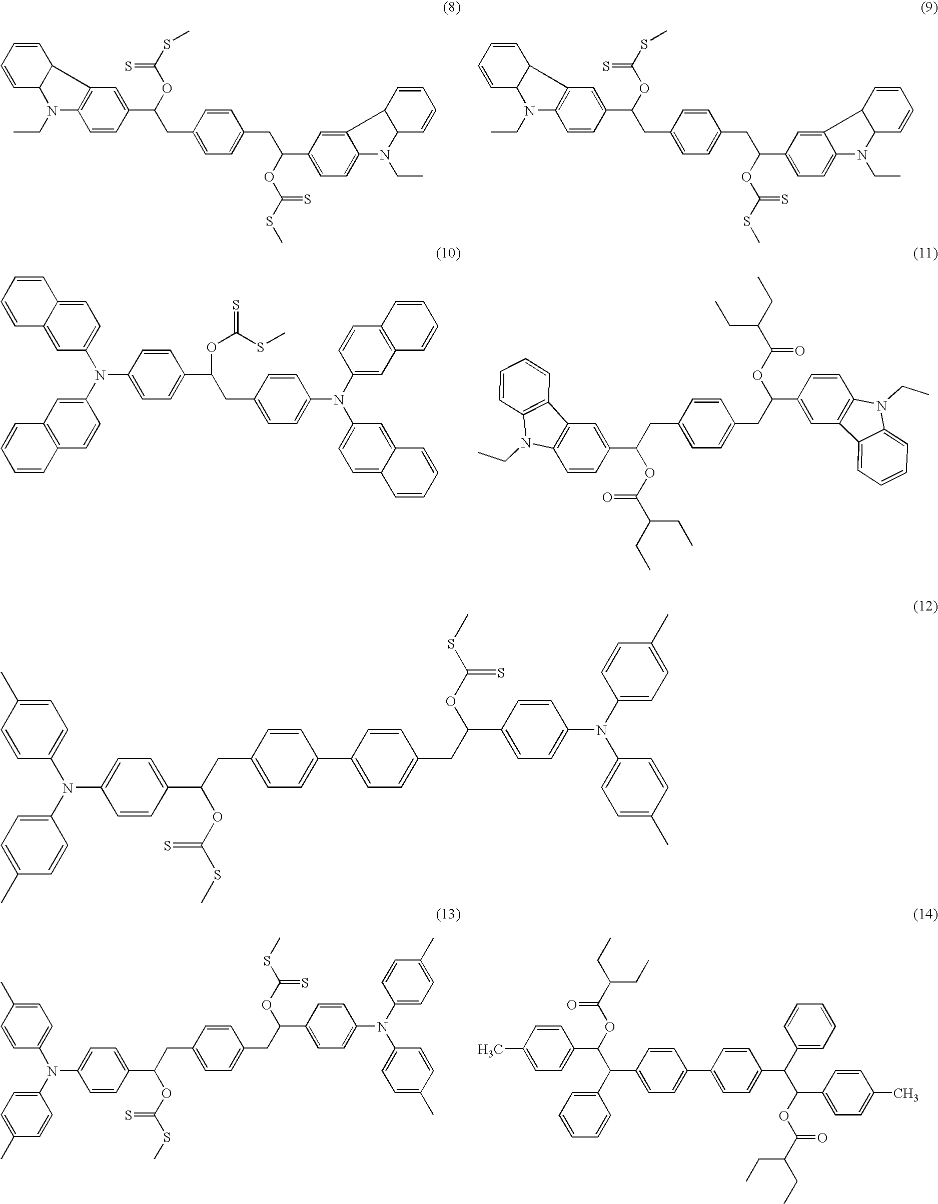

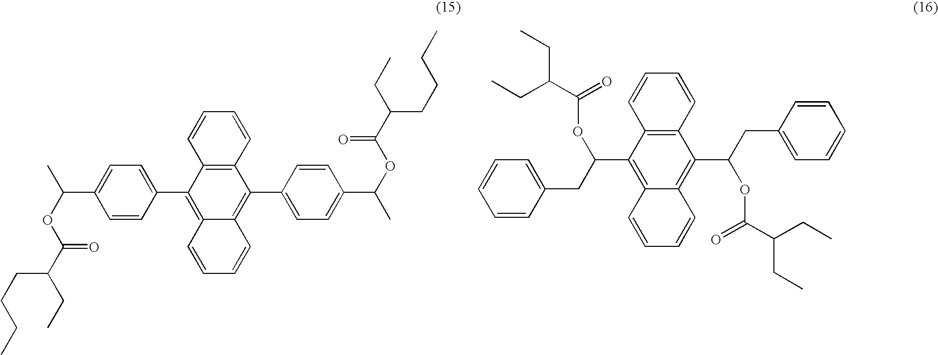

11. The arylene derivative of claim 1, wherein the solubility of the arylene derivative in an organic solvent at 20° C. is more than 0.1% by weight.

12. An organic light emitting device, comprising:
a first electrode;
a second electrode; and
an organic layer interposed between the first electrode and the second electrode, the organic layer formed by forming a layer comprising the arylene derivative of claim 1 by a wet method or a laser induced thermal imaging method and thermolyzing the layer comprising the arylene derivative.

13. An organic light emitting device, comprising:
a first electrode;
a second electrode; and
an organic layer interposed between the first electrode and the second electrode, the organic layer formed by forming a layer having an arylene derivative represented by Formula 1 and thermolyzing the layer having the arylene derivative: 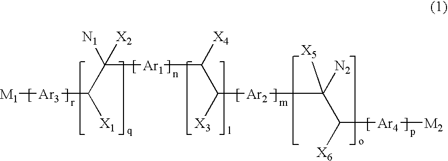
where Ar₁, Ar₂, Ar₃, and Ar₄ are each independently a substituted or unsubstituted C₆-C₃₀ arylene group, or a substituted or unsubstituted C₂-C₃₀ heteroarylene group;
M₁ and M₂ are each independently hydrogen, 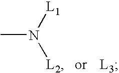
L₁, L₂, and L₃ are each independently a substituted or unsubstituted C₆-C₃₀ aryl group or a substituted or unsubstituted C₂-C₃₀ heteroaryl group; L₁ and L₂ may be connected to form a substituted or unsubstituted ring with the N atom;
N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;
at least one of X₁ and X₂, X₃ and X₄, and X₅ and X₆ are 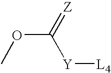
where Y is sulfur, carbon, nitrogen, or oxygen, Z is sulfur or oxygen, L₄ is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, a substituted or unsubstituted C₂-C₃₀ heteroaryl group, an alkoxy group, an alkylamine group, or a thioalkyl group;
l, o and q are each integers of 0 or 1;
1+o+q is an integer of 1 through 3; and
m, n, p and r are each integers of 0 through 3.

14. The organic light emitting device of claim 13, wherein the formation of the layer having the arylene derivative is performed by using a laser induced thermal imaging method or a wet method selected from the group consisting of spin coating, inkjet printing, spray printing, and heat transferring.

15. The organic light emitting device of claim 13, wherein the temperature of the thermolysis is in the range of 100 to 500° C.

16. The organic light emitting device of claim 13, wherein the organic layer is one of an emitting layer and a hole transport layer.

17. The organic light emitting device of claim 13, further comprising at least one layer selected from the group consisting of a hole injection layer, a hole transport layer, an electron blocking layer, a hole blocking layer, an electron transport layer, and an electron injection layer between the first electrode and the second electrode.

18. The organic light emitting device of claim 13, wherein the device has a structure of one selected from the group of a first electrode/hole injection layer/light emitting layer/electron transport layer/electron injection layer/second electrode structure, a first electrode/hole injection layer/hole transport layer/light emitting layer/electron transport layer/electron injection layer/second electrode structure, and a first electrode/hole injection layer/hole transport layer/light emitting layer/hole blocking layer/electron transport layer/electron injection layer/second electrode structure.

19. The organic light emitting device of claim 16, wherein the light emitting layer includes one of a phosphorescent and fluorescent dopant which emits red, green, blue, or white light.

20. An organic light emitting device, comprising:
a first electrode;
a second electrode; and
an organic layer interposed between the first electrode and the second electrode, the organic layer comprising a styryl-based compound formed by thermally-treating an arylene derivative represented by Formula 1: 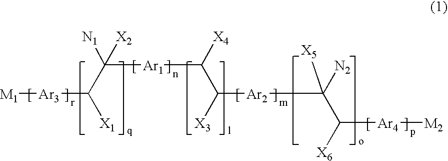
where Ar₁, Ar₂, Ar₃, and Ar₄ are each independently a substituted or unsubstituted C₆-C₃₀ arylene group, or a substituted or unsubstituted C₂-C₃₀ heteroarylene group;
M₁ and M₂ are each independently hydrogen, 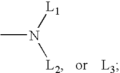
L₁, L₂, and L₃ are each independently a substituted or unsubstituted C₆-C₃₀ aryl group or a substituted or unsubstituted C₂-C₃₀ heteroaryl group; L₁ and L₂ may be connected to form a substituted or unsubstituted ring with the N atom;
N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;
at least one of X₁ and X₂, X₃ and X₄, and X₅ and X₆ are 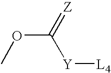
where Y is sulfur, carbon, nitrogen, or oxygen, Z is sulfur or oxygen, 4 is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, a substituted or unsubstituted C₂-C₃₀ heteroaryl group, an alkoxy group, an alkylamine group, or a thioalkyl group;
l, o and q are each integers of 0 or 1;
1+o+q is an integer of 1 through 3; and
m, n, p and r are each integers of 0 through 3.

21. A method of manufacturing an organic light emitting device, comprising:
preparing a first electrode;
forming an organic layer formed on the first electrode, the organic layer including an arylene derivative represented by Formula 1: 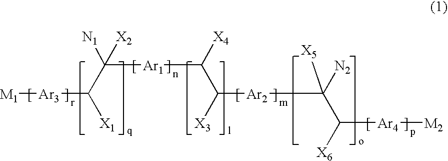
where Ar₁, Ar₂, Ar₃, and Ar₄ are each independently a substituted or unsubstituted C₆-C₃₀ arylene group, or a substituted or unsubstituted C₂-C₃₀ heteroarylene group;
M₁ and M₂ are each independently hydrogen, 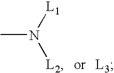
L₁, L₂, and L₃ are each independently a substituted or unsubstituted C₆-C₃₀aryl group or a substituted or unsubstituted C₂-C₃₀ heteroaryl group; L₁ and L₂ may be connected to form a substituted or unsubstituted ring with the N atom;
N₁ and N₂ are each independently, hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, or a substituted or unsubstituted C₂-C₃₀ heteroaryl group;
at least one of X₁ and X₂, X₃ and X₄, and X₅ and X₆ are 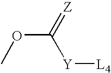
where Y is sulfur, carbon, nitrogen, or oxygen, Z is sulfur or oxygen, L₄ is hydrogen, a substituted or unsubstituted C₁-C₂₀ alkyl group, a substituted or unsubstituted C₁-C₂₀ cycloalkyl group, a substituted or unsubstituted C₁-C₂₀ heterocycloalkyl group, a substituted or unsubstituted C₆-C₃₀ aryl group, a substituted or unsubstituted C₂-C₃₀ heteroaryl group, an alkoxy group, an alkylamine group, or a thioalkyl group;
l, o and q are each integers of 0 or 1;
1+o+q is an integer of 1 through 3; and
m, n, p and r are each integers of 0 through 3; and
thermolyzing the organic layer; and
forming a second electrode on the organic layer after the thermolysis.

22. The method of claim 21, wherein the formation of the organic layer having the arylene derivative is performed by using a laser induced thermal imaging method or a wet method selected from the group consisting of spin coating, inkjet printing, spray printing, and heat transferring.

23. The method of claim 21, wherein the temperature of the thermolysis is in the range of 100 to 500° C.
